(19) United States
(12) Patent Application Publication
(10) Pub. No.: US 2016/0099296 A1
(43) Pub. Date: Apr. 7, 2016

(54) ORGANIC LIGHT-EMITTING DISPLAY APPARATUS

(71) Applicant: Samsung Display Co., Ltd., Yongin-City (KR)

(72) Inventors: Wooseok JEON, Yongin-City (KR); Kyungtea PARK, Yongin-City (KR); Sanghyun JEON, Yongin-City (KR)

(21) Appl. No.: 14/606,792

(22) Filed: Jan. 27, 2015

(30) Foreign Application Priority Data
Oct. 1, 2014 (KR) 10-2014-0132493

(51) Int. Cl. H01L 27/32; H01L 51/52; H01L 51/00

(52) U.S. Cl. CPC H01L 27/3258; H01L 27/3262; H01L 51/0096; H01L 51/5206; H01L 51/5234

(57) ABSTRACT

An organic light-emitting display apparatus includes a substrate; a plurality of pixels provided on a first surface of the substrate and each comprising a first area configured to emit light and a second area configured to have external light transmit therethrough; a pixel circuit unit provided in the first area of each of the plurality of pixels and comprising at least one thin-film transistor (TFT); a first electrode provided in the first area of each of the plurality of pixels and electrically connected to the pixel circuit unit; a second electrode facing the plurality of first electrodes, electrically connected throughout the plurality of pixels, and provided in at least in the first area of each of the plurality of pixels; an intermediate layer disposed between the first electrode and the second electrode and comprising an organic emission layer; and an inorganic insulating film provided in the second area of each of the plurality of pixels, and comprising a plurality of layers having different refractive indices, wherein at least one of the plurality of layers has a moth eye structure.

### RELATED APPLICATION

This application claims the benefit of Korean Patent Application No. 10-2014-0132493, filed on Oct. 1, 2014, in the Korean Intellectual Property Office, the disclosure of which is incorporated herein in its entirety by reference.

### BACKGROUND

1. Field

One or more exemplary embodiments relate to an organic light-emitting display apparatus, and more particularly, to a see-through organic light-emitting display apparatus that is capable of recognizing not only an image realized by the see-through organic light-emitting display apparatus, but also an external background image.

2. Description of the Related Art

An organic light-emitting display apparatus includes an organic light-emitting device that includes a hole injection electrode, an electron injection electrode, and an organic emission layer disposed between the hole injection electrode and the electron injection electrode. The organic light-emitting display apparatus is a self-emissive display apparatus that generates light as excitons generated as holes injected from the hole injection electrode and electrons injected from the electron injection electrode combine in the organic emission layer change from an excited state to a ground state.

Since the organic light-emitting display apparatus that is a self-emissive display apparatus does not need a separate light source, the organic light-emitting display apparatus may be driven by a low voltage, may be light-weighted and thin, and may have excellent viewing angle, contrast, and response speed. Thus, application ranges of the organic light-emitting display apparatus are expanding from personal portable devices, such as MP3 players or mobile phones, to televisions (TV).

Recently, a see-through organic light-emitting display apparatus that enables a user to recognize not only an image realized by the see-through organic light-emitting display apparatus, but also an external background image is being studied.

### SUMMARY

One or more exemplary embodiments include an organic light-emitting display apparatus.

Additional aspects will be set forth in part in the description which follows and, in part, will be apparent from the description, or may be learned by practice of the presented embodiments.

According to one or more embodiments, an organic light-emitting display apparatus includes a substrate; a plurality of pixels provided on a first surface of the substrate and each including a first area configured to emit light and a second area configured to have external light transmit therethrough; a pixel circuit unit provided in the first area of each of the plurality of pixels and including at least one thin-film transistor (TFT); a first electrode provided in the first area of each of the plurality of pixels and electrically connected to the pixel circuit unit; a second electrode facing the plurality of first electrodes, electrically connected throughout the plurality of pixels, and provided in at least in the first area of each of the plurality of pixels; an intermediate layer disposed between the first electrode and the second electrode and including an organic emission layer; and an inorganic insulating film provided in the second area of each of the plurality of pixels, and including a plurality of layers having different refractive indices, wherein at least one of the plurality of layers has a moth eye structure.

The first surface corresponding to at least the second area of the substrate may have the moth eye structure.

A second surface in an opposite side of the first surface of the substrate may have the moth eye structure.

The substrate may be a glass substrate or a plastic substrate.

A buffer layer may be disposed between the substrate and the inorganic insulating film, and have the moth eye structure in top and bottom surfaces thereof.

The buffer layer may include a double layer formed of SiO₂ and SiNₓ.

The TFT may include: an active layer provided on the substrate; a gate electrode provided on and insulated from the active layer; a gate insulating film disposed between the active layer and the gate electrode; an interlayer insulating film provided on the gate electrode; and source and drain electrodes provided on the interlayer insulating film and electrically connected to the active layer, respectively.

The inorganic insulating film may include a first layer formed on the same layer and formed of the same material as the gate insulating film and a second layer formed on the same layer and formed of the same material as the interlayer insulating film.

The first and second layers of the inorganic insulating film respectively may include a double layer formed of SiO₂ and SiNₓ.

A refractive index of the SiOₓ may be about 1.5, and a refractive index of the SiNₓ may be about 1.9.

The second electrode may include a first transmission window formed in a location corresponding to the second area.

The organic light-emitting display apparatus may further include: a planarization film covering the pixel circuit unit; and a pixel defining film covering both edges of the first electrode, wherein the planarization film and the pixel defining film respectively include second and third transmission windows formed in locations corresponding to the second area.

According to one or more embodiments, an organic light-emitting display apparatus includes: a substrate having a moth eye structure formed on a first surface; a plurality of pixels provided on the first surface of the substrate and each including a first area configured to emit light and a second area configured to have external light transmit therethrough; a pixel circuit unit provided in the first area of each of the plurality of pixels and including at least one thin-film transistor (TFT); a first electrode provided in the first area of each of the plurality of pixels and electrically connected to the pixel circuit unit; a second electrode facing the plurality of first electrodes, electrically connected throughout the plurality of pixels, and provided in at least the first area of each of the plurality of pixels; and an intermediate layer disposed between the first electrode and the second electrode and including an organic emission layer.

A second surface in an opposite side of the first surface of the substrate may have the moth eye structure.

The organic light-emitting display apparatus may further include: an inorganic insulating film provided in the second area on the first surface of the substrate, and including a plurality of layers having different refractive indices, wherein at least one of the plurality of layers has the moth eye structure.

A buffer layer may be disposed between the substrate and an inorganic insulating film, and have the moth eye structure in top and bottom surfaces thereof.

The inorganic insulating film may include first and second layers including a double layer formed of SiO₂ and SiNₓ.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic cross-sectional view of an organic light-emitting display apparatus according to an embodiment;

FIG. 2 is a schematic plan view of a pixel included in the organic light-emitting display apparatus of FIG. 1, according to an embodiment;

FIG. 3 is a schematic cross-sectional view of a part of a pixel included in an organic light-emitting display apparatus, according to an embodiment;

FIGS. 4A and 4B are cross-sectional views of a moth eye structure;

FIG. 5 is a schematic cross-sectional view of a transmission area of an organic light-emitting display apparatus according to an embodiment;

FIG. 6 is a cross-sectional view sequentially showing a method of manufacturing a substrate included in the organic light-emitting display apparatus of FIG. 5, according to an embodiment;

FIG. 7 is a schematic cross-sectional view of a transmission area of an organic light-emitting display apparatus according to an embodiment; and

FIG. 8 is a schematic cross-sectional view of a part of a pixel included in an organic light-emitting display apparatus according to an embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present description.

In the drawings, like reference numerals refer to like elements throughout and overlapping descriptions shall not be repeated.

It will be understood that although the terms “first”, “second”, etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, area, or component is referred to as being “formed on,” another layer, area, or component, it can be directly or indirectly formed on the other layer, area, or component. That is, for example, intervening layers, areas, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto.

As used herein, the term “and/or” includes any and all combinations of one or more of the associated listed items. Expressions such as “at least one of” when preceding a list of elements, modify the entire list of elements and do not modify the individual elements of the list.

Hereinafter, one or more exemplary embodiments will be described in detail with reference to accompanying drawings.

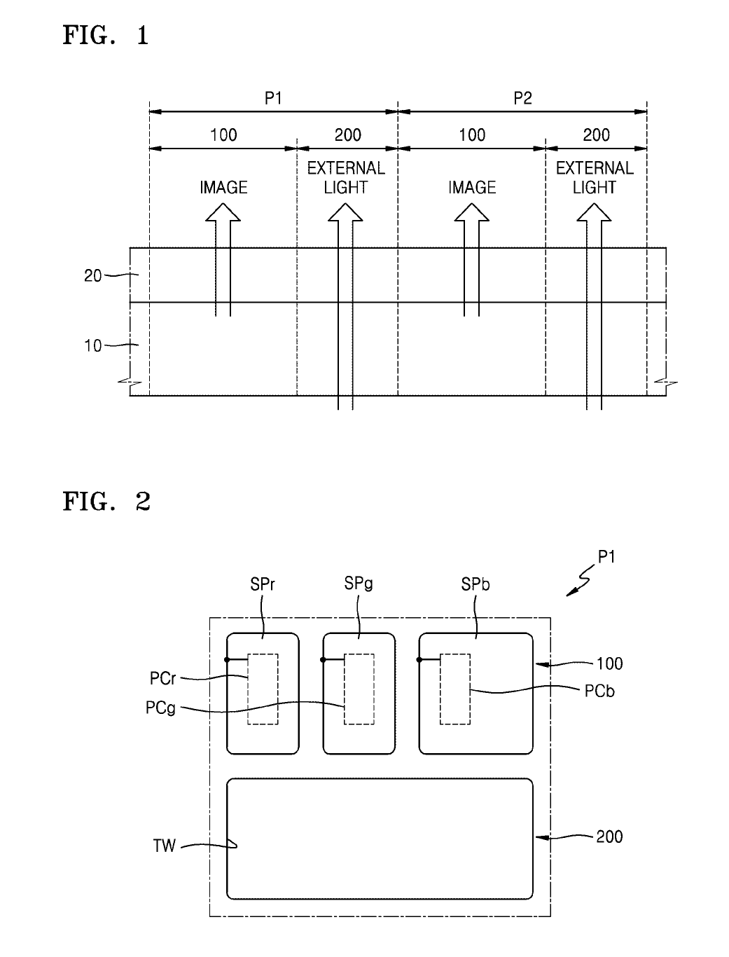

FIG. 1 is a schematic cross-sectional view of an organic light-emitting display apparatus according to an embodiment.

Referring to FIG. 1, the organic light-emitting display apparatus according to an exemplary embodiment includes a substrate 10 and a display unit 20 that is disposed on the substrate 10 and includes a plurality of pixels each including a first area 100 from which light is emitted and a second area 200 through which external light transmits. The external light which is incident on the organic light-emitting display apparatus propagate towards a user after passing through the substrate 10 and the display unit 20.

The display unit 20 is light-transmissive as will be described below, and a user located at a side where an image is realized may observe an image outside the substrate 10. In FIG. 1, the organic light-emitting display apparatus is a top emission type wherein an image of the display unit 20 is realized in a direction opposite to the substrate 10, but a type of the organic light-emitting display apparatus is not limited thereto. In other words, the organic light-emitting display apparatus may be a bottom emission type wherein an image of the display unit 20 is realized in a direction of the substrate 10, or a dual type wherein an image of the display unit 20 is realized in a direction of the substrate 10 and in a direction opposite to the substrate 10.

In FIG. 1, a first pixel P1 and a second pixel P2, which are adjacent to each other, in the organic light-emitting display apparatus are displayed. Each of the first and second pixels P1 and P2 includes the first area 100 and the second area 200, wherein an image is displayed by the display unit 20 through the first area 100 and external light passes through the second area 200.

In other words, since each pixel of the organic light-emitting display apparatus includes the first area 100 in which an image is realized and the second area 200 through which external light transmits, a user may view an image realized by the display unit 20 and/or an external background image through the organic light-emitting display apparatus.

External light transmittance of the second area 200 may be increased by not arranging a thin-film transistor (TFT), a capacitor, and an organic light-emitting device in the second area 200, thereby increasing external light transmittance of the organic light-emitting display apparatus, and preventing an external background image from being distorted due to interference by a TFT, a capacitor, or an organic light-emitting device.

FIG. 2 is a schematic plan view of the first pixel P1 included in the organic light-emitting display apparatus of FIG. 1, according to an embodiment.

Referring to FIG. 2, the first pixel P1 included in the display unit 20 of FIG. 1 includes the first area 100 from which light is emitted, and the second area 200 through which external light transmits, and the user may view the external background image through the second area 200. In other words, the organic light-emitting display apparatus may be realized as a transparent display.

A first sub-pixel SPr, a second sub-pixel SPg, and a third sub-pixel SPb, which emit different colored lights, may be arranged in the first area 100, and may respectively emit red light, green light, and blue light, but are not limited thereto. Any color combination is possible as long as white light is emitted.

The first sub-pixel SPr, the second sub-pixel SPg, and the third sub-pixel SPb may be respectively driven by a first pixel circuit unit PCr, a second pixel circuit unit PCg, and a third pixel circuit unit PCb.

The first pixel circuit unit PCr, the second pixel circuit unit PCg, and the third pixel circuit unit PCb may be arranged to planarly overlap a first electrode 121 of FIG. 3 included in each of the first sub-pixel SPr, the second sub-pixel SPg, and the third sub-pixel SPb.

Such a structure is suitable to a top emission type organic light-emitting display apparatus, wherein the first electrode 121 is a reflective electrode and a second electrode 123 of FIG. 3 is a transparent or semi-transparent electrode. In addition, by disposing the first pixel circuit unit PCr, the second pixel circuit unit PCg, and the third pixel circuit unit PCb between the substrate 10 and the first electrode 121, a separate space for disposing the first pixel circuit unit PCr, the second pixel circuit unit PCg, and the third pixel circuit unit PCb may not be required, thereby increasing an aperture ratio.

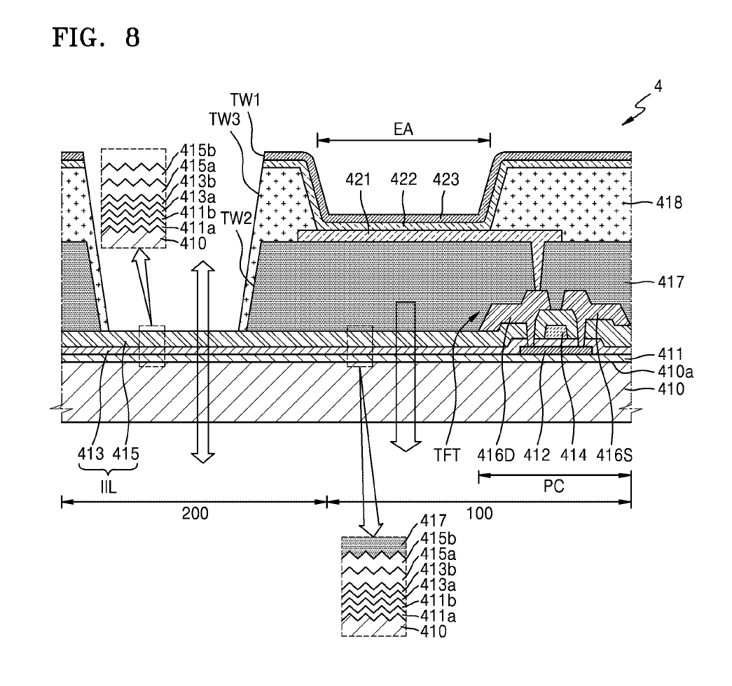

However, the inventive concept is not limited thereto. An organic light-emitting display apparatus according to another embodiment may be a bottom emission type, wherein a first electrode 421 of FIG. 8 is a transparent or semi-transparent electrode and a second electrode 423 of FIG. 8 is a reflective electrode. In this case, a pixel circuit unit including a TFT of FIG. 8 may not planarly overlap the first electrode 421 of FIG. 8 such that a path of emitted light is not interfered.

A device that includes an opaque material, such as a reflective electrode or a wire, is not disposed in the second area 200, and only a transparent insulating film may be disposed in the second area 200. The second area 200 may be defined by an opaque wire that is disposed on a boundary of the first pixel P1. A transmission window TW having a higher transmittance than that of another area may be disposed in the second area 200.

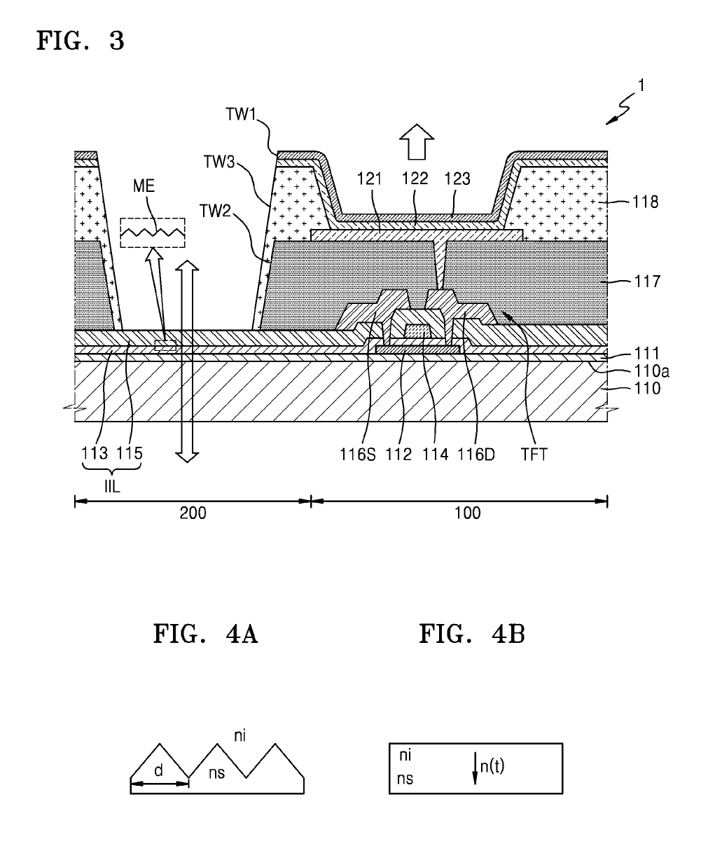

FIG. 3 is a schematic cross-sectional view of a part of a pixel included in an organic light-emitting display apparatus 1, according to an embodiment. FIGS. 4A and 4B are cross-sectional views of a moth eye ME structure.

Referring to FIG. 3, the organic light-emitting display apparatus 1 according to an embodiment includes a substrate 110, a plurality of pixels (for example, the first and second pixels P1 and P2 of FIG. 1) that are disposed on a first surface 110a of the substrate 110 and each includes the first area 100 from which light is emitted and the second area 200 through which external light transmits, a plurality of pixel circuit units (for example, the first pixel circuit unit PCr, the second pixel circuit unit PCg, and the third pixel circuit unit PCb of FIG. 2) that are disposed in the first area 100 of each pixel and each includes at least one TFT, a plurality of the first electrodes 121 that are each disposed in the first areas 100 of the pixels and electrically connected to the pixel circuit units, the second electrode 123 that faces the first electrodes 121, is electrically connected throughout the pixels, and is disposed on at least the first area 100 of each pixel, and an intermediate layer 122 that is disposed between the first electrode 121 and the second electrode 123 and includes an organic emission layer.

An inorganic insulating film IIL including a plurality of layers 113 and 115 having different refractive indices may be disposed in the second area 200. At least one of the plurality of layers 113 and 115 may have the moth eye ME structure.

The substrate 110 may be formed of glass or plastic, and a buffer layer 111 may be disposed on the first surface 110a of the substrate 110. The buffer layer 111 prevents impure elements from penetrating through the substrate 110, planarizes a surface of the substrate 110, and may be a single layer or a multi-layer formed of an inorganic material, such as silicon nitride (SiNₓ) and/or silicon oxide (SiOₓ).

The inorganic insulating film IIL may be disposed on the second area 200 of the buffer layer 111 and include the first layer 113 and the second layer 115. The first layer 113 may be formed on the same layer as and may be formed of the same material as the gate insulating film. The second layer 115 may be formed on the same layer as and may be formed of the same material as the interlayer insulating film. These will be described later.

Each of the first and second layers 113 and 115 may be the single layer or the multi-layer formed of SiNₓ and/or SiOₓ. For example, the first and second layers 113 and 115 may be each formed as a single film and may have different refractive indices.

The first layer 113 may have the moth eye ME structure formed on a top surface thereof. The second layer 115 may be provided on the first layer 113. That is, a boundary surface of the first and second layers 113 and 115 may have the moth eye ME structure.

The moth eye ME structure is a structure including a plurality of unevenesses that do not reflect light irrespective of an incident angle or a wavelength of incident light and are arranged at a gap d smaller than a visible ray wavelength. The unevenesses may have quadrangular or conical cone shapes.

The second area 200 may be a transmission area through which external light transmits and in which light incident into the organic light-emitting display apparatus 1 from the outside may be reflected on a boundary surface between layers having different refractive indices. Such a Fresnel reflection may deteriorate transmittance of the second area 200.

However, the organic light-emitting display apparatus 1 according to an embodiment may minimize an interface reflection by forming the boundary surface between the plurality of layers 113 and 115 disposed in the second area 200 and having different refractive indices to have the moth eye ME structure.

Referring to FIGS. 4A and 4B, when a visible light is incident into the moth eye ME structure including the plurality of unevenesses having a refractive index nₛ of a value greater than that of a refractive index n, such as air and formed at the gap d smaller than the visible ray wavelength as shown in FIG. 4A, the incident light travels in the same path as light is incident into a medium of which refractive index continuously varies from nᵢ to nₛ as shown in FIG. 4B. That is, the moth eye ME structure of FIG. 4A may be the same as the structure of FIG. 4B.

Therefore, when the external light is incident into the inorganic insulating film IIL of which refractive index continuously varies, since the Fresnel reflection does not occur, transmittance of the second area 200 may be improved.

The TFT is disposed on the buffer layer 111 in the first area 100, and includes an active layer 112, a gate electrode 114 that is insulated from the active layer 112, and a source electrode 116S and a drain electrode 116D, which are electrically connected to the active layer 112, respectively. The gate insulating film that is formed on the same layer as and of the same material as the first layer 113 of the inorganic insulating film IIL may be disposed between the active layer 112 and the gate electrode 114. The interlayer insulating film that is formed on the same layer as and of the same material as the second layer 115 of the inorganic insulating film IIL may be disposed between the gate electrode 114 and the source and drain electrodes 116S and 116D.

That is, the gate insulating film and the interlayer insulating film may be extensions of the first layer 113 and the second layer 115, respectively, and may be single films having different refractive indices.

The TFT is a top gate type wherein the gate electrode 114 is disposed on the active layer 112, but is not limited thereto. The gate electrode 114 may be disposed below the active layer 112.

The active layer 112 may contain various materials. For example, the active layer 112 may contain an inorganic semiconductor material, such as amorphous silicon or crystalline silicon. Alternatively, the active layer 112 may contain an oxide semiconductor or an organic semiconductor material.

The gate electrode 114 may be a single layer or a multilayer formed of at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and for example, may be three layers of Mo/Al/Mo or Ti/Al/Ti.

Each of the source and drain electrodes 116S and 116D may include at least two metal layers formed of a material selected from Al, Pt, Pd, Ag, Mg, Au, Ni, Nd, Ir, Cr, Li, Ca, Mo, Ti, W, Cu, and an alloy thereof.

A planarization film 117 may be disposed on the interlayer insulating film to cover the source and drain electrodes 116S and 116D. The first electrode 121 electrically connected to the drain electrode 116D, the second electrode 123 facing the first electrode 121, and the intermediate layer 122 disposed between the first and second electrodes 121 and 123 and including the organic emission layer that emits light may be disposed on the planarization film 117.

Two edges of the first electrode 121 may be covered by a pixel-defining film 118. The planarization film 117 and the pixel-defining film 118 may each be formed of an organic material. The planarization film 117 may function to cover and planarize elements, such as the TFT. The pixel-defining film 118 may function to define the first area 100, i.e., an emission area, prevent an electric field from concentrating at an edge of the first electrode 121, and prevent the first and second electrodes 121 and 123 from being short-circuited.

The first electrode 121 may be a reflective electrode, and may include a reflective layer formed of Ag, mg, Al, Pt, Pd, Au, Ni, Nd, Ir, Cr, or a compound thereof, and a transparent or semi-transparent electrode layer formed on the reflective layer. The first electrodes 121 may be independent island shapes according to sub-pixels.

The second electrode 123 may be a transparent or semi-transparent electrode, may be formed of at least one material from Ag, Al, Mg, Li, Ca, Cu, LiF/Ca, LiF/Al, MgAg, and CaAg, and may be a thin-film having a thickness from several to dozens of nm. The second electrode 123 may be electrically connected throughout all pixels included in the organic light-emitting display apparatus 1.

The second electrode 123 may include a first transmission window TW1 formed in a location corresponding to the second area 200. The planarization film 117 and the pixel-defining film 118 may respectively include a second transmission window TW2 and a third transmission window TW3 formed in locations corresponding to the second area 200. That is, the second electrode 123, the planarization film 117, and the pixel-defining film 118 are not disposed in the transmission window TW of FIG. 2 of the second area 200, thereby further improving the transmittance of the second area 200.

The intermediate layer 122 may be disposed between the first and second electrodes 121 and 123. The intermediate layer 122 includes an organic emission layer that emits light, and may further include at least one of a hole injection layer (HIL), a hole transport layer (HTL), an electron transport layer (ETL), and an electron injection layer (EIL). However, an embodiment is not limited thereto, and various functional layers may be further disposed between the first and second electrodes 121 and 123.

The organic emission layer may emit red light, green light, or blue light. However, an embodiment is not limited thereto, and the organic emission layer may emit white light. In this case, the organic emission layer may have a structure in which a light-emitting material emitting red light, a light-emitting material emitting green light, and a light-emitting material emitting blue light are stacked on one another, or a structure in which a light-emitting material emitting red light, a light-emitting material emitting green light, and a light-emitting material emitting blue light are mixed.

The red, greed, and blue colors are exemplary and an embodiment is not limited thereto. In other words, any combination of other various colors, which is capable of emitting white light, may be employed in addition to a combination of red, green, and blue colors.

The organic light-emitting display apparatus 1 according to an embodiment may be a top emission type that realizes an image in a direction of the second electrode 123, and the plurality of pixel circuit units PCr, PCg, and PCb of FIG. 2 including the TFT, etc., may be disposed between the substrate 110 and the first electrode 121.

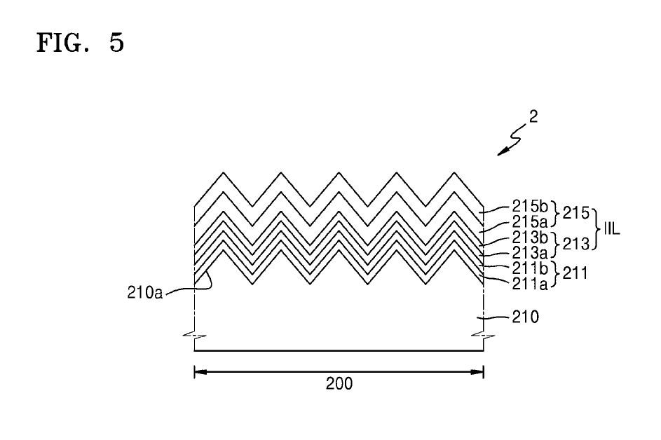

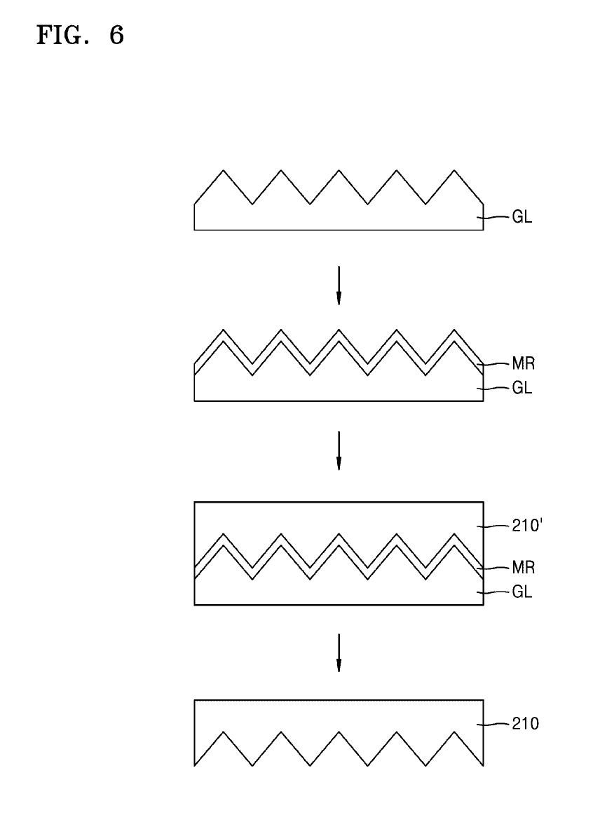

FIG. 5 is a schematic cross-sectional view of a transmission area of an organic light-emitting display apparatus 2 according to an embodiment. FIG. 6 is a cross-sectional view sequentially showing a method of manufacturing a substrate included in the organic light-emitting display apparatus 2 of FIG. 5, according to an embodiment.

Referring to FIG. 5, the second area 200 of the organic light-emitting display apparatus 2 according to an embodiment may include a substrate 210, a buffer layer 211 provided on a first surface 210a of the substrate 210, and the inorganic insulating film ILL provided on the buffer layer 211.

The substrate 210 may be a glass substrate or a plastic substrate formed of polyimide. The first surface 210a may have a moth eye structure. The moth eye structure may be formed only in an area corresponding to the second area 200 or may be formed in all areas of the organic light-emitting display apparatus 2.

When the substrate 210 is the glass substrate, the moth eye structure may be formed through nano imprinting that uses heat or ultraviolet rays, etching that uses an ordered anodic porous alumina mask, self assembling, etc. of which detailed descriptions are omitted.

FIG. 6 schematically shows a method of forming the substrate 210 when the substrate 210 is the plastic substrate formed of polyimide.

To form the substrate 210, a mold release MR may be coated on glass GL formed by using the above-described methods, and then a polyimide film 210′ may be coated on the mold release MR. The polyimide film 210′ may be cured and separated from the glass GL, thereby forming the plastic substrate 210.

The buffer layer 211 may be provided on the substrate 210, and have top and bottom surfaces having the moth eye structure. The buffer layer 211 may include double layers 211a and 211b formed of silicon nitride (SiNₓ) and silicon oxide (SiOₓ). Not only the top and bottom surfaces of the buffer layer 211 but also a boundary surface between the layer 211a formed of silicon nitride (SiNₓ) and the layer 211b formed of silicon oxide (SiOₓ) may have the moth eye structure.

The inorganic insulating film IIL may be provided on the buffer layer 211, and may include a first layer 213 and a second layer 215. The first layer 213 may include double layers 213a and 213b formed of silicon nitride (SiNₓ) and silicon oxide (SiOₓ). The second layer 215 may include double layers 215a and 215b formed of silicon nitride (SiNₓ) and silicon oxide (SiOₓ). A refractive index of silicon oxide (SiOₓ) may be about 1.5. A refractive index of silicon nitride (SiNₓ) may be about 1.9.

The buffer layer 211 and the inorganic insulating film IIL are formed on the first surface 210a of the substrate 210 having the moth eye structure, and thus the buffer layer 211 and the layers 211a, 211b, 213a, 213b, 215a, and 215b included in the inorganic insulating film IIL may naturally have the moth eye structure, thereby efficiently preventing reflection from boundary surfaces between layers having different refractive indices.

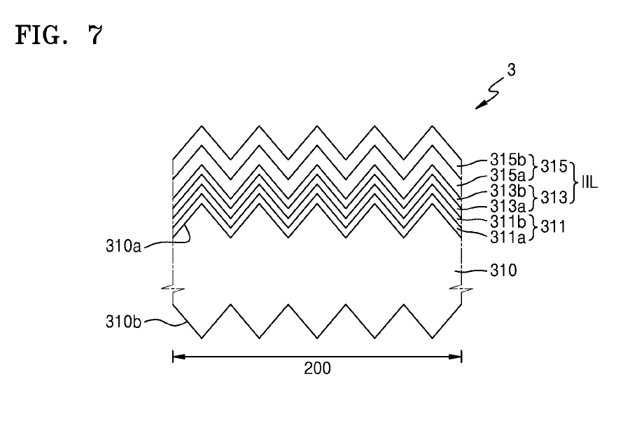

FIG. 7 is a schematic cross-sectional view of a transmission area of an organic light-emitting display apparatus 3 according to an embodiment.

Referring to FIG. 7, the second area 200 of the organic light-emitting display apparatus 3 according to an embodiment may include a substrate 310, a buffer layer 311 provided on a first surface 310a of the substrate 310, and the inorganic insulating film ILL provided on the buffer layer 311.

The substrate 310 may be a glass substrate or a plastic substrate formed of polyimide. The first surface 310a and a second surface 310b in an opposite side of the first surface 310a may have a moth eye structure. The moth eye structure may be formed only in an area corresponding to the second area 200 or may be formed in all areas of the organic light-emitting display apparatus 3.

The buffer layer 311 may be provided on the substrate 310, and have top and bottom surfaces having the moth eye structure. The buffer layer 311 may include double layers 311a and 311b formed of silicon nitride (SiNₓ) and silicon oxide (SiOₓ). Not only the top and bottom surfaces of the buffer layer 311 but also a boundary surface between silicon nitride (SiNₓ) and silicon oxide (SiOₓ) may have the moth eye structure.

The inorganic insulating film IIL may be provided on the buffer layer 311, and may include a first layer 313 and a second layer 315. The first layer 313 may include double layers 313a and 313b formed of silicon nitride (SiNₓ) and silicon oxide (SiOₓ). The second layer 315 may include double layers 315a and 315b formed of silicon nitride (SiNₓ) and silicon oxide (SiOₓ). A refractive index of silicon oxide (SiOₓ) may be about 1.5. A refractive index of silicon nitride (SiNₓ) may be about 1.9.

The second surface 310b of the substrate 310 may correspond to a outermost surface of the organic light-emitting display apparatus 3, and may have the moth eye structure, thereby efficiently preventing external light reflection of the organic light-emitting display apparatus 3.

In particular, when the organic light-emitting display apparatus 3 is a bottom emission type, the second surface 310b of the substrate 310 may have the moth eye structure, and thus external light reflection may be efficiently prevented without a polarizer, thereby improving visibility of the organic light-emitting display apparatus 3.

FIG. 8 is a schematic cross-sectional view of a part of a pixel included in an organic light-emitting display apparatus 4 according to an embodiment.

Referring to FIG. 8, the organic light-emitting display apparatus 4 according to an embodiment may include a substrate 410 partitioned by the first area 100 and the second area 200 through which external light transmits, and a buffer layer 411 provided on a first surface 410a of the substrate 410.

The substrate 410 may be a glass substrate or a plastic substrate formed of polyimide. The buffer layer 411 may include double layers 411a and 411b formed of silicon nitride (SiNₓ) and silicon oxide (SiOₓ).

The substrate 410 may have a moth eye structure formed on the first surface 410a. The buffer layer 411 may have the moth eye structure formed in top and bottom surfaces thereof and a boundary surface between the layer 411a formed of silicon nitride (SiNₓ) and the layer 411b formed of silicon oxide (SiOₓ).

The first area 100 provided on the buffer layer 411 may include a pixel circuit unit PC in which a TFT including an active layer 412, a gate electrode 414, a source electrode 416S, and a drain electrode 416D may be provided.

A planarization film 417 planarizing circuit devices such as the TFT may be provided on the TFT. The first electrode 421 electrically connected to the drain electrode 416D, a second electrode 423 disposed to face the first electrode 421, and an intermediate layer 422 disposed between the first electrode 421 and the second electrode 423 and including an organic emission layer emitting light may be provided on the planarization film 417.

Both edges of the first electrode 421 may be covered by a pixel defining film 418.

The first electrode 421 may include a transparent conductive layer and a semi-transmittance layer. The transparent conductive layer may be at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). The semi-transmittance layer may include at least one selected from the group consisting of Ag, Mg, Al, Pt, Pd, Au, Ni, Nd, Ir, Cr, Li, Ca, and Yb and may be formed of a thin film of several nm to several tens nm.

The second electrode 423 may be a reflective electrode and may include at least one selected from the group consisting of Ag, Al, Mg, Li, Ca, Cu, LiF/Ca, LiF/Al, MgAg, and CaAg.

The second electrode 423 may include the first transmission window TW1 formed in a location corresponding to the second area 200. The planarization film 417 and the pixel defining film 418 may also include a second transmission window TW2 and a third transmission window TW3 formed in locations corresponding to the second area 200, respectively. That is, the second electrode 423, the planarization film 417, and the pixel defining film 418 are not provided in the transmission window TW of FIG. 2 of the second area 200, thereby improving transmittance of the second area 200.

The intermediate layer 422 may be disposed between the first and second electrodes 421 and 423. The intermediate layer 422 includes the organic emission layer that emits light, and may further include at least one of a hole injection layer (HIL), a hole transport layer (HTL), an electron transport layer (ETL), and an electron injection layer (EIL), but is not limited thereto. Various functional layers may be further disposed between the first and second electrodes 421 and 423.

The organic light-emitting display apparatus 4 according to an embodiment may be a bottom emission type in which an image is formed in a direction of the substrate 410. The pixel circuit unit PC including the TFT may be provided not to overlap with an emission area EA defined by the pixel defining film 418. That is, light emitted by the intermediate layer 422 may be emitted to the outside without an interference of circuit elements included in the pixel circuit unit PC.

The inorganic insulating film !IL may be provided in the second area 200 on the buffer layer 411, and may include a first layer 413 and a second layer 415. The first layer 413 may include double layers 413a and 413b formed of silicon oxide (SiOₓ) and silicon nitride (SiNₓ). The second layer 415 may include double layers 415a and 415b formed of silicon oxide (SiOₓ) and silicon nitride (SiNₓ). A refractive index of silicon oxide (SiOₓ) may be about 1.5. A refractive index of silicon nitride (SiNₓ) may be about 1.9. The layers 413a, 413b, 415a, and 415b included in the inorganic insulating film IIL may have a moth eye structure formed in top and bottom surfaces.

The buffer layer 411 and the inorganic insulating film IIL are formed on the first surface 410a of the substrate 410 including the moth eye structure, and thus the buffer layer 411 and the layers 413a, 413b, 415a, and 415b included in the inorganic insulating film IIL may naturally have the moth eye structure, thereby efficiently preventing reflection from boundary surfaces between layers having different refractive indices.

The moth eye structure formed in the substrate 410, the buffer layer 411, and the inorganic insulating film IL may be included in not only an area corresponding to the second area 200 but also an area corresponding to the emission area EA.

The structure may improve the transmittance of the second area 200 and prevent the light emitted by the intermediate layer 422 from being reflected from boundary surfaces between layers having different refractive indices provided on a light path, thereby improving light efficiency.

As described above, according to one or more exemplary embodiments, a see-through organic light-emitting display apparatus having improved transmittance may be realized.

While one or more exemplary embodiments have been described with reference to the figures, it will be understood by those of ordinary skill in the art that various changes in form and details may be made therein without departing from the spirit and scope as defined by the following claims.

1. An organic light-emitting display apparatus comprising:
a substrate;
a plurality of pixels provided on a first surface of the substrate and each comprising a first area configured to emit light and a second area configured to have external light transmit therethrough;
a pixel circuit unit provided in the first area of each of the plurality of pixels and comprising at least one thin-film transistor (TFT);
a first electrode provided in the first area of each of the plurality of pixels and electrically connected to the pixel circuit unit;
a second electrode facing the plurality of first electrodes, electrically connected throughout the plurality of pixels, and provided in at least in the first area of each of the plurality of pixels;
an intermediate layer disposed between the first electrode and the second electrode and comprising an organic emission layer; and
an inorganic insulating film provided in the second area of each of the plurality of pixels on the substrate, and comprising a first layer and a second layer contacting with the first layer having different refractive indices,
wherein the first layer has a moth eye structure in a surface contacting with the second layer.

2. The organic light-emitting display apparatus of claim 1, wherein the first surface corresponding to at least the second area of the substrate has the moth eye structure.

3. The organic light-emitting display apparatus of claim 2, wherein a second surface in an opposite side of the first surface of the substrate has the moth eye structure.

4. The organic light-emitting display apparatus of claim 2, wherein the substrate is a glass substrate or a plastic substrate.

5. The organic light-emitting display apparatus of claim 1, wherein a buffer layer is disposed between the substrate and the inorganic insulating film, and has the moth eye structure in top and bottom surfaces thereof.

6. The organic light-emitting display apparatus of claim 5, wherein the buffer layer comprises a double layer formed of SiO₂ and SiNₓ.

7. The organic light-emitting display apparatus of claim 1, wherein the TFT comprises:
an active layer provided on the substrate;
a gate electrode provided on and insulated from the active layer;
a gate insulating film disposed between the active layer and the gate electrode;
an interlayer insulating film provided on the gate electrode; and
source and drain electrodes provided on the interlayer insulating film and electrically connected to the active layer, respectively.

8. The organic light-emitting display apparatus of claim 7, wherein the first layer of the inorganic insulating film formed on the same layer and formed of the same material as the gate insulating film and the second layer of the inorganic insulating film formed on the same layer and formed of the same material as the interlayer insulating film.

9. The organic light-emitting display apparatus of claim 8, wherein the first and second layers of the inorganic insulating film respectively comprise a double layer formed of SiO₂ and SiNₓ.

10. The organic light-emitting display apparatus of claim 9, wherein a refractive index of the SiOₓ is about 1.5, and a refractive index of the SiNₓ is about 1.9.

11. The organic light-emitting display apparatus of claim 1, wherein the second electrode comprises a first transmission window formed in a location corresponding to the second area.

12. The organic light-emitting display apparatus of claim 11, further comprising:
a planarization film covering the pixel circuit unit; and
a pixel defining film covering both edges of the first electrode,
wherein the planarization film and the pixel defining film respectively comprise second and third transmission windows formed in locations corresponding to the second area.

13. An organic light-emitting display apparatus comprising:
a substrate having a first surface;
a buffer layer disposed on the first surface of the substrate and contacting the first surface of the substrate;
a plurality of pixels provided on the buffer layer and each comprising a first area configured to emit light and a second area configured to have external light transmit therethrough;
a pixel circuit unit provided in the first area of each of the plurality of pixels and comprising at least one thin-film transistor (TFT);
a first electrode provided in the first area of each of the plurality of pixels and electrically connected to the pixel circuit unit;
a second electrode facing the plurality of first electrodes, electrically connected throughout the plurality of pixels, and provided in at least the first area of each of the plurality of pixels; and
an intermediate layer disposed between the first electrode and the second electrode and comprising an organic emission layer,
wherein the substrate has a moth eye structure in the first surface contacting with the buffer layer.

14. The organic light-emitting display apparatus of claim 13, wherein a second surface in an opposite side of the first surface of the substrate has the moth eye structure.

15. The organic light-emitting display apparatus of claim 13, further comprising:
an inorganic insulating film provided in the second area on the first surface of the substrate, and comprising a plurality of layers having different refractive indices,
wherein at least one of the plurality of layers has the moth eye structure.

16. The organic light-emitting display apparatus of claim 13, wherein a buffer layer is disposed between the substrate and an inorganic insulating film, and has the moth eye structure in top and bottom surfaces thereof.

17. The organic light-emitting display apparatus of claim 15, wherein the inorganic insulating film comprises first and second layers comprising a double layer formed of SiO₂ and SiNₓ.
